(19) United States
(12) Patent Application Publication
(10) Pub. No.: US 2008/0049411 A1
(43) Pub. Date: Feb. 28, 2008

(54) I/O shield and electronic apparatus using the same

(75) Inventors: Chun-Min Wang, Taipei (TW); Sheng-Hung Wang, Taipei (TW); Jian-Sheng Hsieh, Taipei (TW)

Correspondence Address: BIRCH STEWART KOLASCH & BIRCH, PO BOX 747, FALLS CHURCH, VA, 22040-0747, US

(73) Assignee: ASUSTeK COMPUTER INC.

(21) Appl. No.: 11/822,377

(22) Filed: Jul. 5, 2007

(30) Foreign Application Priority Data
Aug. 25, 2006 (TW) 95131446

(51) Int. Cl. H05K 9/00

(52) U.S. Cl. 361/818

(57) ABSTRACT

An I/O shield used in an electronic apparatus is provided. The electronic apparatus comprises a casing having an opening. The I/O shield comprises a body and at least a flexible lateral plate. The body has an edge with many protrusions arranged thereon. The flexible lateral plate has a first lateral edge and a second lateral edge parallel to the first lateral edge. The first lateral edge is disposed on the edge. The flexible lateral plate tilts towards the protrusions, and a surface of the flexible lateral plate faces the protrusions. When a rim of the opening is situated between the protrusions and the flexible lateral plate, the flexible lateral plate forms a bend structure between the first lateral edge and the second lateral edge, so that part of the surface near the second lateral edge presses the rim and clamps the rim of the opening together with the protrusions.

This application claims the benefit of Taiwan application Serial No. 95131446, filed Aug. 25, 2006, the subject matter of which is incorporated herein by reference.

### BACKGROUND OF THE INVENTION

1. Field of the Invention

The invention relates in general to a technology field of preventing electrostatic discharge (ESD) and electromagnetic interference (EMI), and more particularly to an I/O shield and an electronic apparatus using the same.

2. Description of the Related Art

Referring to FIG. 1, the appearance of a conventional computer is shown. The computer 100 includes a casing 110 and an I/O shield 120. The casing 110 can accommodate hardware equipments such as optical disc drive, hard disk drive and motherboard. The I/O shield 120 disposed in the opening O of the casing 110 is made from a conductive material such as stainless steel and is an element sold together with the motherboard. The I/O shield 120 prevents electrostatic discharge (ESD), electromagnetic interference (EMI) and dusts and prettifies the appearance of the electronic apparatus. Besides, the I/O ports of the motherboard are respectively connected to different peripheral equipment, such as keyboard or mouse, via several connecting holes H of the I/O shield 120. Meanwhile, the I/O shield 120 restricts the position of each plug inserted into the I/O port, hence having the function of fixation.

Referring to FIG. 2, a cross-sectional view along the cross-sectional line A-A′ of the computer 100 of FIG. 1 is shown. The righthand side of FIG. 2 denotes the inside of the casing 110. The I/O shield 120 includes a body 120a and four lateral plates 120b respectively disposed on four edges of the body 120a. Let the edge E of the body 120a of FIG. 1 be taken for example. The body 120a further includes a plurality of protrusions p. The protrusions p are arranged on the edge E at an equal interval, and the lateral plates 120b on the edge E are disposed along the direction of the edge E and approximately have the same length with the edge E.

For the convenience of disassembly, normally the body 120a of the I/O shield 120 is cut into the same size with the opening O. As indicated in FIG. 2, the width of the body 120a is approximately equal to the interval between the rim E′ and the rim F′ of the opening O (the length also has the same relationship). During assembly, the I/O shield 120 is pushed out from the position corresponding to the opening O inside the casing 110. For example, the rim E′ corresponding to the rim E is situated between the protrusion p and the lateral plate 120b, and contacts the protrusion p and the top edge e of the lateral plate 120b. The remaining three edges are installed in the same manner. Thus, the I/O shield 120 is fixed on the casing 110 and can form electrical connection via the contact with the casing 110, in this case, the rim E′. As the casing 110 is grounded, the accumulation of electrostatic charges that may damage the motherboard or other elements inside the casing 110 is reduced, and the leakage of electromagnetic waves is avoided.

However, the I/O shield 120 and the casing 110 which are cut out by automatic equipment have a certain level of manufacturing tolerance, that is, the size of the body 120a does not completely match with the opening O. Or, the same problem may arise when the user uses various parts from different makers to assemble a computer. Because the I/O shield that comes with the motherboard may not match with the casing from another maker. If the thickness of the casing (rim) does not match with the interval between the protrusion and the lateral plate, a gap will be generated, the I/O shield will become loose inside the opening, the top edges of the four lateral plates and the protrusion will have loose contact with the rim of the opening. In addition to the problem that the conventional I/O shield can not be fixed on the casing firmly, the efficiency of preventing electrostatic discharge and electromagnetic interference is largely decreased. There exists a different manner of fixing the I/O shield by screwing the I/O shield onto the casing. However, the design of fixing the I/O shield by screws not only makes the assembly and disassembly of the I/O shield inconvenient, but also incurs more manufacturing costs.

### SUMMARY OF THE INVENTION

The invention is directed to an I/O shield and an electronic apparatus using the same. The I/O shield uses at least a flexible lateral plate to increase the contact area with the casing of the electronic apparatus and to increase the stability of fixing the I/O shield onto the casing. Compared with the conventional design, the I/O shield of the invention enhances both the ability of preventing electrostatic discharge and the ability of preventing electromagnetic interference, so that the operation of the electronic apparatus is well protected.

According to a first aspect of the present invention, an I/O shield used in an electronic apparatus is provided. The electronic apparatus includes a casing having an opening. The I/O shield includes a body and at least a flexible lateral plate. The body has an edge and a plurality of protrusions arranged on the edge. The flexible lateral plate has a first lateral edge and a second lateral edge parallel to the first lateral edge. The first lateral edge is disposed on the edge. The flexible lateral plate tilts towards the protrusions, and a surface of the flexible lateral plate faces the protrusions. When a rim of the opening is situated between the protrusions and the flexible lateral plate, the flexible lateral plate forms a bend structure between the first lateral edge and the second lateral edge, so that part of the surface near the second lateral edge firmly presses the rim and clamps the rim of the opening together with the protrusions

According to a second aspect of the present invention, an electronic apparatus including a casing and an I/O shield is provided. The casing has an opening. The I/O shield includes a body and at least a flexible lateral plate. The body has an edge and a plurality of protrusions arranged on the edge. The flexible lateral plate has a first lateral edge and a second lateral edge parallel to the first lateral edge. The first lateral edge is disposed on the plane. The flexible lateral plate tilts towards the protrusions, and a surface of the flexible lateral plate faces the protrusions. When a rim of the opening is situated between the protrusions and the flexible lateral plate, the flexible lateral plate forms a bend structure between the first lateral edge and the second lateral edge, so that part of the surface near the second lateral edge firmly presses the rim and clamps the rim together with the protrusions.

The invention will become apparent from the following detailed description of the preferred but non-limiting embodiments. The following description is made with reference to the accompanying drawings.

### BRIEF DESCRIPTION OF THE DRAWINGS

FIG. 1 illustrates the appearance of a conventional computer;

FIG. 2 is a cross-sectional view along the cross-sectional line A-A′ of the computer of FIG. 1;

FIG. 3 is a front view of the I/O shield according to a preferred embodiment of the invention;

FIG. 4A is a diagram of the flexible lateral plate of FIG. 3 disposed on edge;

FIG. 4B is a side view of FIG. 4A; and

FIGS. 5A and 5B are two diagrams of the I/O shield disposed in the opening of the casing.

### DETAILED DESCRIPTION OF THE INVENTION

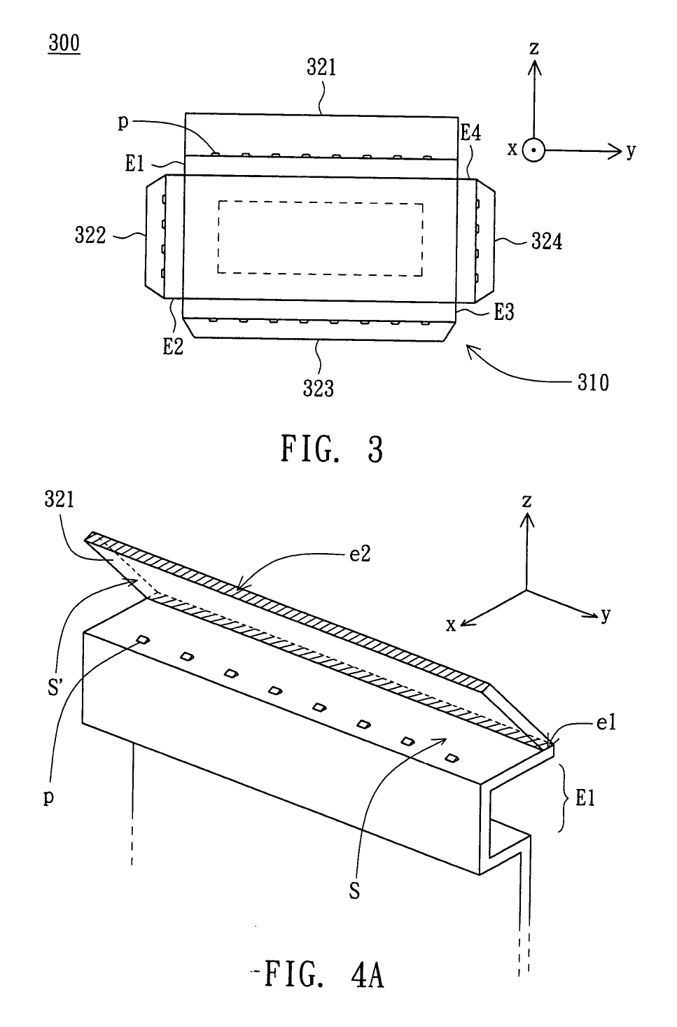

Referring to FIG. 3, a front view of the I/O shield according to a preferred embodiment of the invention is shown. The I/O shield 300 includes a body 310, a flexible lateral plate 321, and three lateral plates 322, 323 and 324. The body 310 has four edges E1, E2, E3 and E4, and several protrusions p arranged on the four edges E1˜E4.

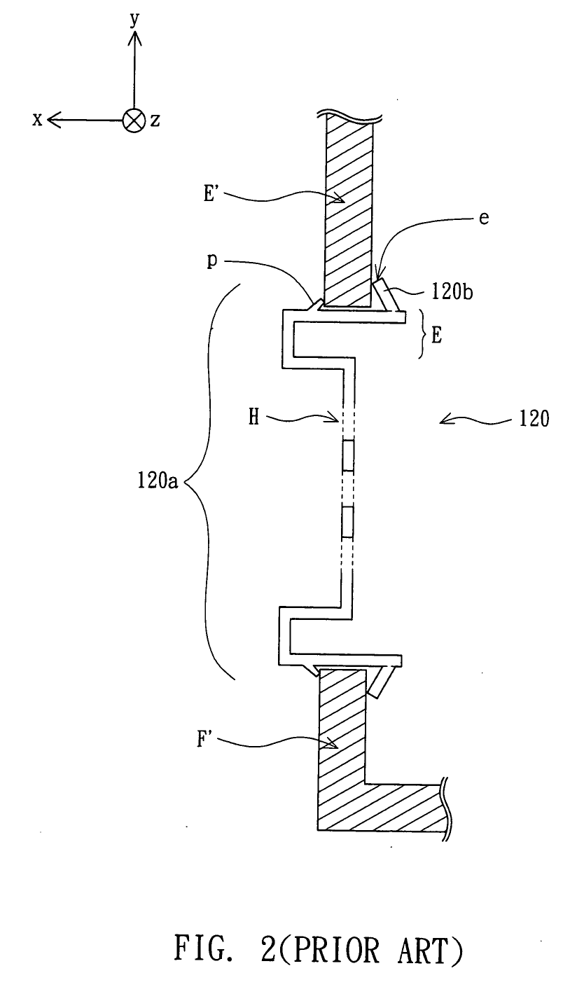

The dotted frame at the center of the body 310 denotes the location of conventional connecting holes H (as shown in FIG. 2), and relevant illustrations are omitted in FIG. 3. The flexible lateral plate 321 and the three lateral plates 322˜324 are respectively disposed on the edges E1˜E4. In the present embodiment of the invention, the design of the three lateral plates 322˜324 and the protrusions p disposed on the corresponding edges E1˜E4 is the same as that of the conventional design (as shown in FIG. 2), and is not repeated here. However, in other embodiments, the flexible lateral plate can be disposed on the three remaining edges, or, the same edge can have many flexible lateral plates disposed thereon in parallel. The disposition of the flexible lateral plate 321 is further elaborated below.

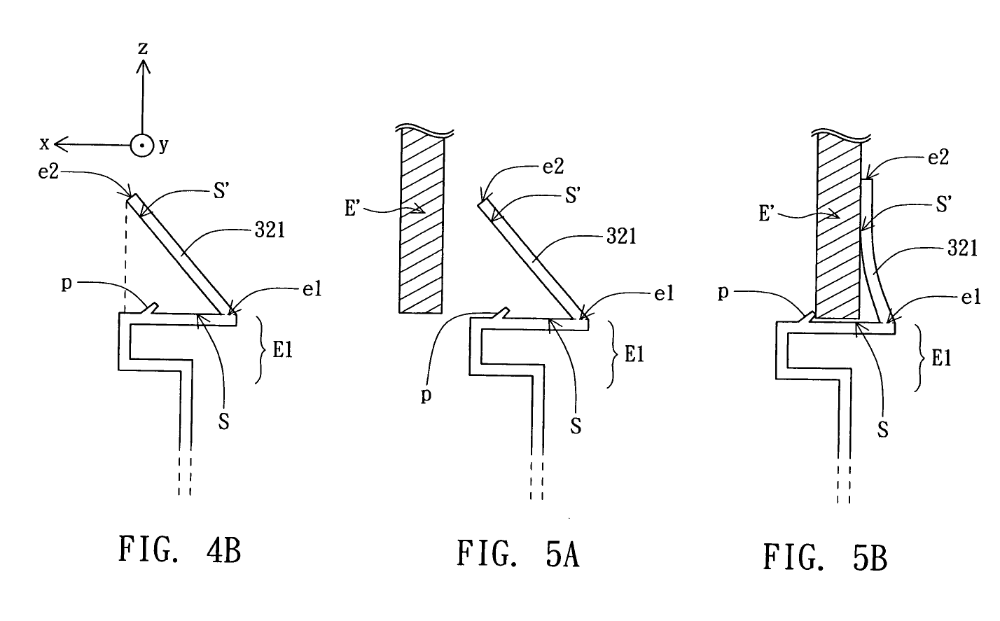

Referring to FIGS. 4A and 4B. FIG. 4A is a diagram of the flexible lateral plate 321 of FIG. 3 disposed on edge E1. FIG. 4B is a side view of FIG. 4A. In FIG. 4A, the relevant illustrations of the three remaining edges E2˜E4 are omitted. As indicated in FIG. 4A, the edge E1 is an inverted U-shaped structure for forming a plane S. The flexible lateral plate 321 has a first lateral edge e1 and a second lateral edge e2 parallel to the first lateral edge e1 (denoted by two slope-line areas in FIG. 4A). The first lateral edge e1 is disposed on the plane S of the edge E1. Several protrusions p are arranged on the plane S at an equal interval. Furthermore, as indicated in FIG. 4A, the flexible lateral plate 321 tilts towards the protrusions p, and the surface S′ of the flexible lateral plate 321 faces the protrusions p.

In the present embodiment of the invention, the flexible lateral plate 321 is made from a conductive material such as metal or stainless steel, and the material of the flexible lateral plate 321 can be different from that of the body 310. In other embodiments, the flexible lateral plate 321 can be made from the same material with that of the body 310. The flexible lateral plate 321 and the body 310 can be integrally formed in one piece, or the flexible lateral plate 321 can be soldered onto the edge E1 (for example, the first lateral edge e1 is spot soldered onto the plane S). Any method enabling the flexible lateral plate 321 to be connected to the edge E1 and to tilt toward the protrusions p as shown in FIG. 4A can be applied herein.

Basically, the width (the distance between the first lateral edge e1 and the second lateral edge e2) and the inclination angle of the flexible lateral plate 321, and the intervals between the first lateral edge e1 and the protrusion p are not subjected to any specific restrictions. The width of the flexible lateral plate 321 is determined according to the material of the flexible lateral plate 321 and must be wide enough for providing flexibility between the first lateral edge e1 and the second lateral edge e2. That is, the second lateral edge e2 of FIG. 4B can be bent to the right (towards the reverse direction of direction x), and the flexible lateral plate 321 forms a bend structure between the first lateral edge e1 and the second lateral edge e2 for generating a restoring elasticity applied leftward. In the present embodiment of the invention, in response to the assembly of the I/O shield 300 on the casing (a detailed elaboration is stated below), the width of the flexible lateral plate 321 is preferably wide enough for the second lateral edge e2 to slightly exceed the protrusions p, as indicated in the dotted lines extended downwards from the second lateral edge e2 of FIG. 4B. That is, the position of the protrusions p corresponds to the midst of the second lateral edge e2 and the first lateral edge e1. Or, in other embodiments, the width of the flexible lateral plate 321 can be slightly shorter, so that the second lateral edge e2 corresponds to the midst of the protrusions p and the first lateral edge e1, the interval between the second lateral edge e2 and the protrusions p is smaller than the thickness of the casing.

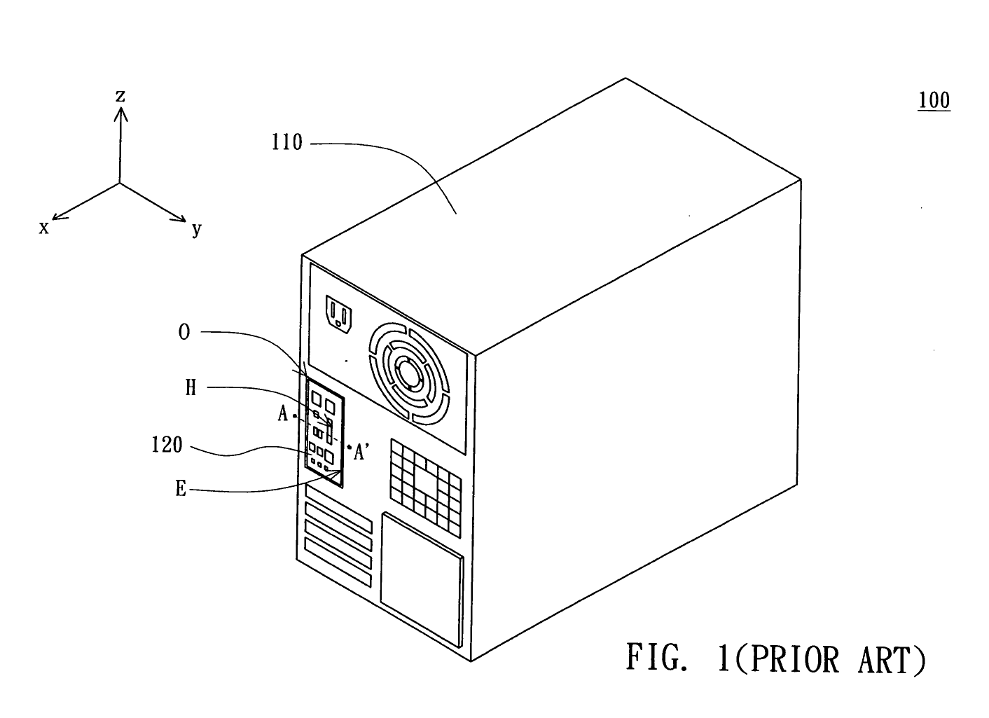

As for how to resolve the conventional problems by means of the flexible lateral plate 321 when the I/O shield 300 is installed in the casing of the electronic apparatus is exemplified by the installation of the I/O shield 300 of the preferred embodiment of the invention in the casing 110 of the computer 100 of FIG. 1, and how the I/O shield 300 of the invention differs from conventional I/O shield 100 is illustrated in accompanied drawings.

Referring to FIGS. 5A and 5B, two diagrams of the I/O shield 300 disposed in the opening O of the casing 110 are shown. FIGS. 5A and 5B only illustrate the edge E1 of the flexible lateral plate 321 and the rim E′ of the opening O of the casing 110. As indicated in FIG. 5A, similarly, the I/O shield 300 is pushed out from inside the casing 100 toward outward the opening O in the manner that the edge E1 is corresponded to the rim E′. In this way, the rim E′ contacts the second lateral edge e2 first. Next, the I/O shield 300 continues to be pushed towards outward the opening O, so that the second lateral edge e2 receives a force from the rim E′ and bends to the right (the internal of the casing 110). When the rim E′ touches and squeezes the protrusion p, the rim E′ slightly presses the inverted U-shaped structure of the edge E1, so that the surface S is slightly pressed downward for the rim E′ to pass through the protrusions p, and then the surface S rises up again.

As indicated in FIG. 5B, when the rim E′ is situated between the protrusions p and the flexible lateral plate 321, the flexible lateral plate 321 forms a bend structure between the first lateral edge e1 and the second lateral edge e2 for generating a restoring elasticity applied leftward. Thus, the part of the surface S′ near the second lateral edge e2 firmly presses the rim E′ and clamps the rim E′ together with the protrusions p.

Compared with the prior art, the I/O shield 300, despite having manufacturing tolerance, is still able to be firmly disposed in the opening O. As the flexible lateral plate 321 generates an elasticity from the bent structure, the rim E′ is clamped between the protrusions p and the flexible lateral plate 321 by a larger force with a larger contact area (in prior art, the contact area between the rim E′ and the lateral plate is limited to the top edge e), largely resolving the problem of loose fastening and poor contact. For example, the anti-electrostatic charge capacity of a conventional electronic apparatus is approximately 8 kV, but the anti-electrostatic charge capacity of electronic apparatus using the I/O shield of the preferred embodiment of the invention reaches 16 kV. Besides, the I/O shield of the invention preferred embodiment is compactible with the casing of existing computers, so there is no need to change the overall frame structure of existing computers. Furthermore, no additional manufacturing costs incur and no specific assembly/dis-assembly is required.

However, any one who is skilled in the field of the invention will understand that the technology of the invention is not limited thereto. For example, if the location of the opening on the casing and the space within the casing permit, the three remaining edges of the I/O shield can also adopt flexible lateral plates, but the width of the flexible lateral plate on each edge does not necessarily be the same. The length of the flexible lateral plate, which is approximately equal to the length of the edge in the above embodiments, can be adjusted according to actual needs. Of the flexible lateral plates disposed on the same edge in parallel, the interval between two neighboring flexible lateral plates can be designed to incorporate the disposition of other elements inside the casing. The I/O shield according to the preferred embodiment of the invention is not only applicable to the computer, but also can be used in whatever electronic apparatus requiring a metal element having similar function on the casing. Any design of the I/O shield using a bent structure of the flexible lateral plate to clamp the rim of the opening with the protrusions for firmly fixing the I/O shield and increasing the contact area between the I/O shield and the casing lies within the scope of protection of the invention.

According to the I/O shield and an electronic apparatus using the same disclosed in the above embodiment of the invention, the I/O shield uses at least a flexible lateral plate to clamp the rim of the opening with several protrusions so as to increase the contact area with the casing of the electronic apparatus and facilitate the I/O shield to be fixed on or detached from the casing. Compared with the conventional design, the I/O shield according to the preferred embodiment of the invention prevents electrostatic discharge and electromagnetic interference so that the operation of the electronic apparatus is well protected.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An I/O shield used in an electronic apparatus comprising a casing having an opening, the I/O shield comprising:
a body having an edge and a plurality of protrusions arranged on the edge; and
at least a flexible lateral plate having a first lateral edge and a second lateral edge parallel to the first lateral edge, wherein the first lateral edge is disposed on the edge of the body, the flexible lateral plate tilts towards the protrusions, and a surface of the flexible lateral plate faces the protrusions;
wherein when a rim of the opening is situated between the protrusions and the flexible lateral plate, the flexible lateral plate forms a bend structure between the first lateral edge and the second lateral edge, so that part of the surface near the second lateral edge firmly presses the rim and clamps the rim of the opening together with the protrusions.

2. The I/O shield according to claim 1, wherein the body and the flexible lateral plate are integrally formed in one piece.

3. The I/O shield according to claim 1, wherein the flexible lateral plate is soldered onto the edge.

4. The I/O shield according to claim 1, wherein the flexible lateral plate and the body are made from different materials.

5. The I/O shield according to claim 1, wherein before the flexible lateral plate forms the bent structure, the position of the second lateral edge corresponds to the midst of the protrusions and the first lateral edge, and the interval between the second lateral edge and the protrusions is less than a thickness of the rim.

6. The I/O shield according to claim 1, wherein before the flexible lateral plate forms the bent structure, the position of the protrusions corresponds to the midst of the second lateral edge and the first lateral edge.

7. An electronic apparatus, comprising:
a casing having an opening; and
an I/O shield, comprising:
a body disposed in the opening and having an edge and a plurality of protrusions arranged on the edge; and
at least a flexible lateral plate having a first lateral edge and a second lateral edge parallel to the first lateral edge, wherein the first lateral edge is disposed on the edge, the flexible lateral plate tilts towards the protrusions, and a surface of the flexible lateral plate faces the protrusions;
wherein when a rim of the opening is situated between the protrusions and the flexible lateral plate, the flexible lateral plate forms a bend structure between the first lateral edge and the second lateral edge of the flexible lateral plate, so that part of the surface near the second lateral edge firmly presses the rim and clamps the rim of the opening together with the protrusions.

8. The electronic apparatus according to claim 7, wherein the body and the flexible lateral plate are integrally formed in one piece.

9. The electronic apparatus according to claim 7, wherein the flexible lateral plate is soldered onto the edge.

10. The electronic apparatus according to claim 7, wherein the apparatus is a computer.
